(19) United States
(12) Patent Application Publication
(10) Pub. No.: US 2013/0177999 A1
(43) Pub. Date: Jul. 11, 2013

(54) METHODS FOR FABRICATING INTEGRATED CIRCUITS INCLUDING IN-LINE DIAGNOSTICS PERFORMED ON LOW-K DIELECTRIC LAYERS

(71) Applicant: Denis Shamiryan, Dresden (DE)

(72) Inventor: Denis Shamiryan, Dresden (DE)

(73) Assignee: GLOBALFOUNDRIES INC., Grand Cayman (KY)

(21) Appl. No.: 13/348,441

(22) Filed: Jan. 11, 2012

(51) Int. Cl. H01L 21/66

(52) U.S. Cl. 438/16; 257/E21.529

(57) ABSTRACT

Methods are provided for fabricating integrated circuits. In accordance with one embodiment an integrated circuit feature is formed overlying a semiconductor substrate. A layer of low dielectric constant insulator is deposited overlying the circuit feature and is subjected to a plasma environment. Properties of the low dielectric constant material are measured by scatterometry. The low dielectric constant material is heated to drive off adsorbed water and then the properties of the material are remeasured by scatterometry. The results of the measuring and the remeasuring are compared to determine whether the low dielectric constant material was damaged by the plasma environment.

### TECHNICAL FIELD

The present invention generally relates to methods for fabricating integrated circuits, and more particularly relates to methods for fabricating integrated circuits including in-line diagnostics performed on low-k dielectric layers.

### BACKGROUND

Insulating layers, and especially low dielectric constant (low-k) insulating layers are used in integrated circuits (ICs) to isolate between conductive layers that provide the wiring and interconnection of individual circuit devices. Low-k layers are used to reduce the capacitive coupling between conductive layers and thus to reduce power consumption and to reduce the RC time constant and increase the operating speed of the IC.

Plasma processing is used extensively in the fabrication of ICs. Plasma processing is used to etch patterns in layers, to remove photoresist and to clean surfaces after various other processes. Unfortunately, insulating layers and especially low-k insulating layers are especially vulnerable to damage by plasma processing. Plasma processing can make low-k materials hydrophilic, that is, adsorbing moisture from the atmosphere. Since water has a high dielectric constant, the damage to low-k insulating layers increases the dielectric constant of the layers resulting in increased capacitive coupling which may be serious enough to cause the IC to fail. Characterization of the damage resulting from processing, especially plasma processing, is necessary to determine whether the affected layer is still adequate for the intended purpose, whether the layer needs to be repaired, or whether the layer has been damaged severely enough to cause processing of the IC to be terminated.

There are a number of available techniques for characterizing damage to blanket (i.e., non-patterned) layers, but it is difficult to characterize damage to patterned layers, for example damage to the sidewalls of a trench etched into the layer. Such damage in blanket layers can be characterized by dipping the layer in hydrofluoric acid (HF) followed by scanning electron microscopy (SEM). The damaged portion is removed by the HF and can be observed by SEM in a cross section taken through the damaged area. The damage can also be characterized by energy-filtered transmission electron microscopy (TEM) of a cross section of the damaged area. Both methods are destructive and time consuming. Infra-red ellipsometry could be used for characterizing damaged structures, but the very long wavelength (much longer than the feature size being observed) makes extraction of the sidewall contribution difficult.

Accordingly, it is desirable to provide methods for fabricating integrated circuits that include in-line diagnostic techniques for evaluating processing damage to insulating layers. Furthermore, other desirable features and characteristics of the present invention will become apparent from the subsequent detailed description and the appended claims, taken in conjunction with the accompanying drawings and the foregoing technical field and background.

### BRIEF SUMMARY

Methods are provided for fabricating integrated circuits. In accordance with one embodiment an integrated circuit feature is formed overlying a semiconductor substrate. A layer of low dielectric constant insulator is deposited overlying the circuit feature and is subjected to a processing environment. Properties of the low dielectric constant material are measured by scatterometry. The low dielectric constant insulator is heated to drive off adsorbed water and then the properties of the insulator are remeasured by scatterometry. The results of the measuring and the remeasuring are compared to determine whether the low dielectric constant insulator was damaged by the plasma environment.

In accordance with a further embodiment the method for fabricating integrated circuits in and on a semiconductor substrate includes depositing a layer of dielectric material overlying the substrate and plasma etching the layer to form a pattern. The optical properties of the layer of pattered dielectric material are measured by scatterometry and the patterned layer is heated. The optical properties of the layer of patterned dielectric material are remeasued by scatterometry after heating and the measured and remeasured optical properties are compared. The extent of change in the layer of dielectric material caused by the plasma etching is determined in response to comparing the measured and remeasured optical properties.

In accordance with yet another embodiment the method for fabricating integrated circuits includes partially fabricating an integrated circuit structure including subjecting a layer of low dielectric constant dielectric material to a processing environment. An in-line diagnostic technique is performed on the structure to determine whether the layer of low dielectric constant dielectric material was damaged by the processing environment. The in-line diagnostic technique includes measuring the optical properties of the layer of low dielectric constant dielectric material, heating the layer, and remeasuring the optical properties of the layer after heating. The measured and remeasured optical properties are compared to determine whether to continue to process the partially fabricated integrated circuit structure.

### BRIEF DESCRIPTION OF THE DRAWINGS

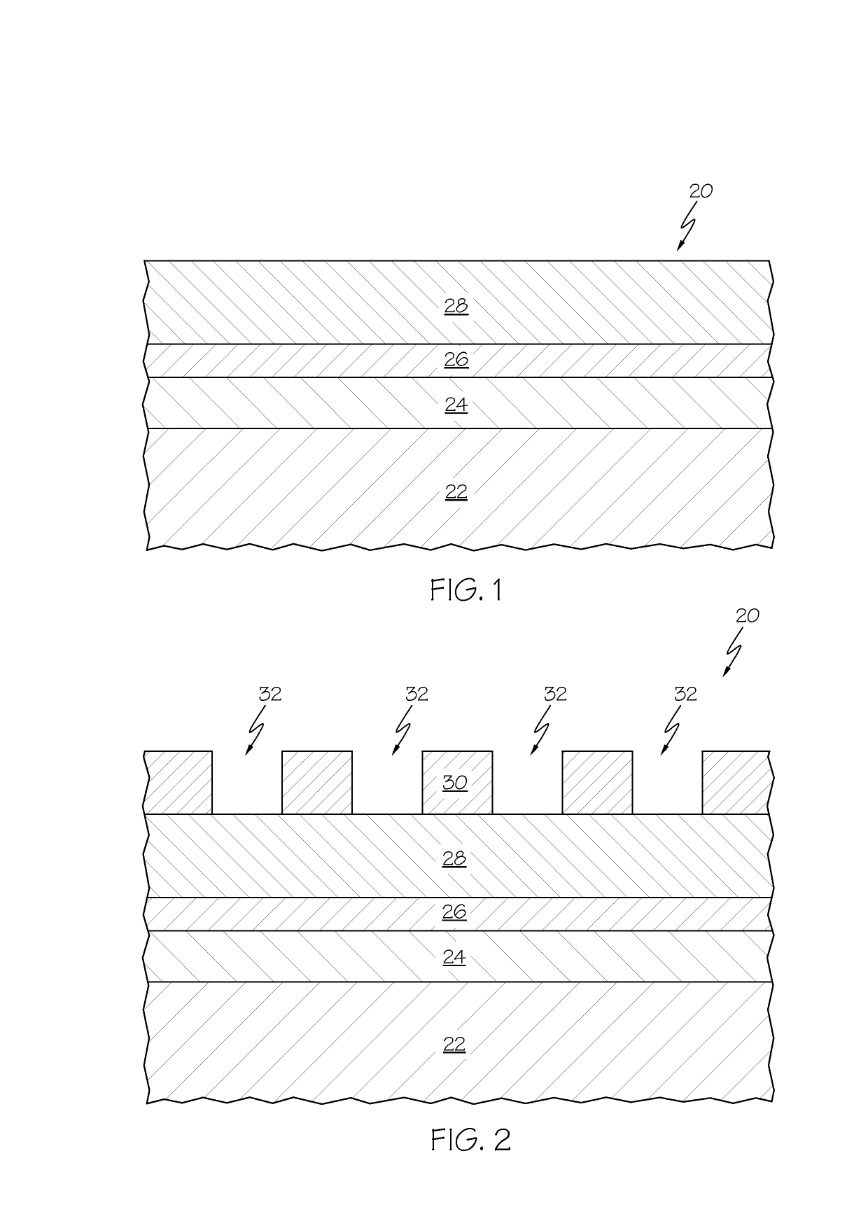

The present invention will hereinafter be described in conjunction with the following drawing figures, wherein like numerals denote like elements, and wherein FIGS. 1-4 schematically illustrate a portion of an integrated circuit and method steps for fabricating an integrated circuit in accordance with various embodiments. FIGS. 1-3 illustrate portions of an integrated circuit in cross-sectional views and FIG. 4 illustrates a further portion of an integrated circuit in a top view.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

Methods for fabricating integrated circuits (ICs) that include in-line diagnostics of insulating layers are provided in accordance with various embodiments. The in-line diagnostics are applicable to characterization of damage to insulating layers, especially low dielectric constant (low-k) insulator layers, caused by subjecting the insulating layers to the various processing environments, especially plasma processing environments, encountered during the IC fabrication. FIGS. 1-4 illustrate portions of an IC 20 fabricated in accordance with embodiments of the inventive methods. Various steps in the fabrication of ICs are well known to those of skill in the art and so, in the interest of brevity, conventional steps will only be mentioned briefly herein or will be omitted entirely without providing the well known process details.

FIG. 1 illustrates, in simplified cross-sectional view, a portion of IC 20 after a number of initial processing steps have been completed. At this stage of processing IC 20 includes semiconductor substrate 22, an overlying circuit feature such as structure 24, and a conductive line 26. Semiconductor substrate 22 can be, for example, silicon, silicon admixed with germanium or other elements, or other material commonly used for the fabrication of ICs. The semiconductor substrate can be a bulk semiconductor wafer or a semiconductor on insulator (SOI) wafer. Overlying structure 24 can be or include insulating layers, patterned layers of polycrystalline silicon, metal layers, and the like formed in early processing steps. Conductive line 26 can be a patterned polycrystalline silicon line or a metal line formed of aluminum, copper, or other highly conductive material. A layer of insulating material 28 is deposited overlying conductive line 26 and will electrically isolate conductive line 26 from subsequently formed overlying conductors. The layer of insulating material, often referred to as an interlayer dielectric (ILD) is, for example, a layer of low dielectric constant (low-k) insulator.

The dielectric constant of an insulating layer separating the two conductors is one factor determining the capacitance between conductive line 26 and any subsequently formed overlying conductors. Reducing such capacitance reduces power consumption and also reduces the RC delay associated with charging or discharging the capacitance. “Low-k” is generally defined as a dielectric constant less than the dielectric constant of silicon dioxide (about 3.9). A low-k insulator can be, for example, silsesquioxane (SSQ) based (the silsesquioxanes are organic-inorganic polymers), fluorine or carbon-doped silica glasses, organic polymers, often fluorinated, SiOCH films, and the like. Such insulators may be porous materials, and steps may be taken to increase the porosity and thereby lower the dielectric constant of the films. ILD films can be deposited, for example, by spin on or chemical vapor deposition techniques, depending on the particular film being deposited.

Methods in accordance with one embodiment continue, as illustrated in simplified cross-sectional view in FIG. 2 by depositing and patterning a layer of photoresist 30 overlying layer of insulating material 28 to form a process mask. The process mask can be, for example, an ion implantation mask or an etch mask. In this embodiment the patterned layer of photoresist serves as an etch mask. Layer of photoresist 30 is exposed and developed to produce a pattern that is to be replicated in the underlying layer of insulating material. In this exemplary embodiment the layer of photoresist is patterned to provide a regular array of open spaces 32 through which the surface of insulating layer 28 is exposed.

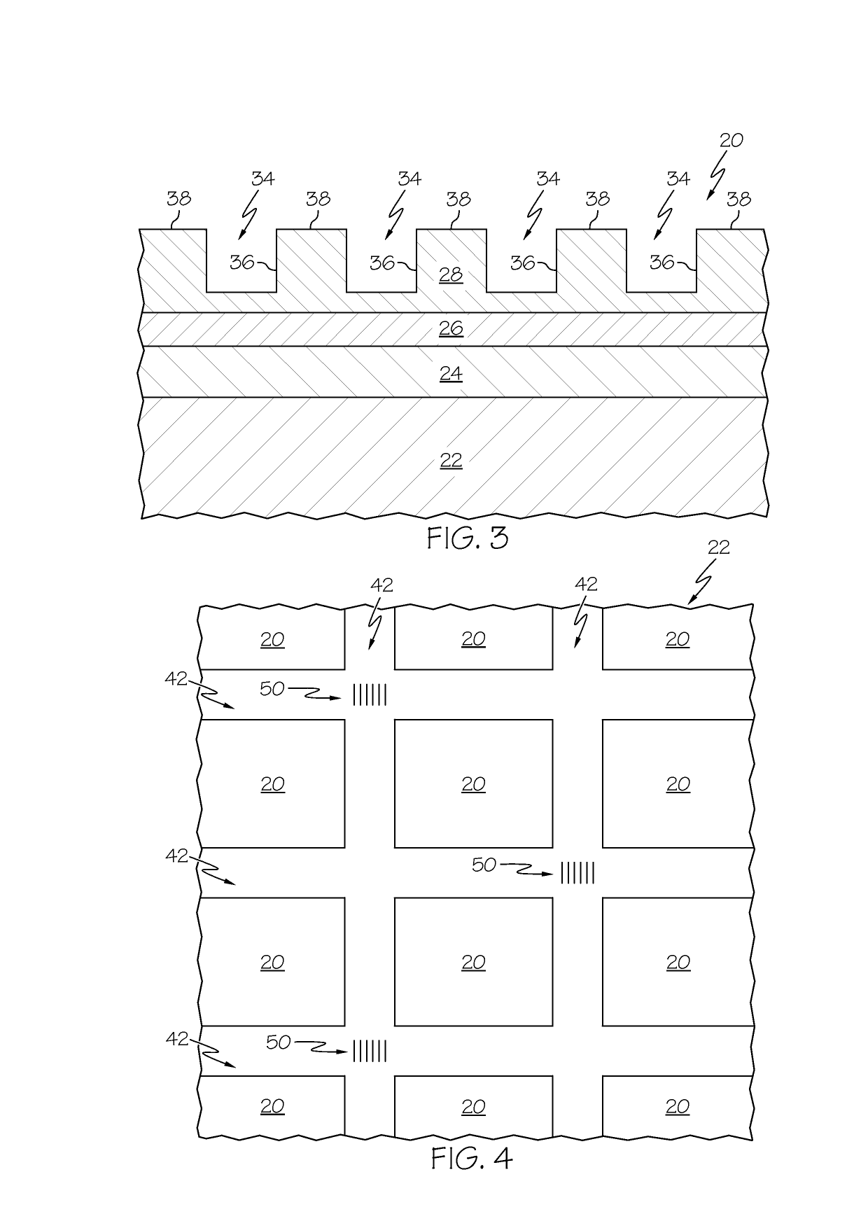

As illustrated in FIG. 3, in accordance with one embodiment, the patterned layer of photoresist is used as an etch mask and trenches 34 are etched into the exposed surface of insulating layer 28. The trenches can be, for example, patterns that subsequently will be filled with copper or other conductive material to form conductors by a damascene process. After trenches 34 are etched, the patterned layer of photoresist is removed.

The process of etching the trenches and removing the patterned photoresist may subject insulating layer 28 to two different plasma processes. Insulating layers and especially low-k insulator layers are often etched by plasma dry etch techniques because of the high anisotropy of the process. For example, fluorocarbon plasma (pure or in combination with oxygen plasma) is commonly used for the etching of inorganic low-k insulators. Oxygen plasma, oxygen/nitrogen plasma, and hydrogen plasma are all used to etch various organic low-k insulators. As noted above, after using the patterned layer of photoresist as a process mask, the layer of photoresist is removed. Layers of photoresist are often removed either by “ashing” in an oxygen plasma or by subjecting the photoresist to a hydrogen plasma. The underlying insulator layer, especially sidewalls 36 of the trenches are exposed to the plasma during the photoresist removal. In addition, insulator layer 28 can be exposed to further plasma treatment to clean the layer prior to any subsequent processing steps.

It is known that exposing insulating layers, especially low-k insulating layers, to certain process environments such as plasma environments can damage the insulating layer. Damage to a low-k insulating layer can raise the dielectric constant of the layer and increase the capacitive coupling between conductors separated by the low-k insulating layer. Because of the possible damage that insulating layers may sustain as a result of exposure to processing environments it is important to be able to monitor the extent of the damage to the insulating layer by an in-line diagnostic tool to determine whether fabrication can continue, whether the layer must be repaired before the fabrication can continue, or whether the damage is so severe that the fabrication must be terminated.

Damaged low-k insulating layers adsorb water from the atmosphere, and water adsorption changes the optical properties of the layer. For example, the index of refraction of the insulating layer increases. Adsorbed water can be desorbed from a damaged low-k insulating layer by heating. Accordingly, in accordance with one embodiment, the extent of damage to an insulating layer caused by interaction with a processing environment can be determined non-destructively by the following technique: measure the optical properties of the processed layer, heat the layer to drive off adsorbed water, and remeasure the optical properties of the layer after heating. A comparison of the optical properties before and after heating provides an indication of the amount of water adsorbed by the processed layer and subsequently desorbed by heating, and hence the extent of damage caused by the processing environment. If the optical properties measured before and after heating are different, it means that water was desorbed from the layer by the heating which means that the layer was damaged by the processing environment. If no difference in the optical properties of the layer is observed after heating, it means that little water was adsorbed by the layer and thus the layer was not damaged by the processing environment. In accordance with one embodiment the optical properties are measured and remeasured by scatterometry.

Scatterometry is a form of ellipsometry in which scatterometry radiation (with wavelengths typically in the range of 190-1700 nm) is incident on a grating structure. In accordance with one embodiment a grating-like structure is formed by the regular array of lines 38 and trenches 34 formed in a layer of low-k insulator such as illustrated in FIG. 3. Such a regular, periodic array can often be identified in some area of each of the ICs being fabricated. Memory arrays, for example, often include regular patterns of lines and spaces. In accordance with another embodiment, as illustrated in FIG. 4, especially if a grating-like structure is not available on the IC being fabricated, an optical grating 50 is formed in the scribe grid of the semiconductor substrate. As is well known, ICs are usually fabricated in a regular array in and on a semiconductor substrate 22, a portion of which is illustrated in plan view in FIG. 4. Individual ICs 20 are separated from each other by a scribe grid 42. The scribe grid provides an area which is used to scribe, saw, laser cut, or otherwise separate the individual ICs at the completion of the fabrication process. The scribe grid can also be used, during fabrication, as a location for test devices, alignment keys, and the like. In accordance with this embodiment, optical gratings 50 are formed in the scribe grid area at the same time and in the same process as trenches 34 were formed in layer 28 of insulator material. That is, layer 28 is blanket deposited overlying the scribe grid as well as the IC itself. Optical gratings 50 are etched in that layer using the same photoresist mask used to pattern trenches 34. Optical gratings 50 can include, for example, a regular array of spaced apart trenches formed in layer 28. In an exemplary embodiment, for example, optical gratings 50 can include a plurality of trenches each having a width of 10 nm spaced apart from the next trench by a space of 10 nm. A number of optical gratings 50 can be formed in a dispersed pattern of locations around the semiconductor wafer. The optical properties of layer 28 can be measured and remeasured by scatterometry or other optical technique by sequentially directing the appropriate scatterometry radiation on a number of optical gratings 50 or on grating-like structures identified on selected ones of ICs 20. By measuring and remeasuring optical properties of processed layer 28 at a number of locations around the semiconductor substrate, a complete characterization of layer 28 and the possible damage to that layer can be obtained. Between the measuring and remeasuring steps, layer 28 is heated, for example to a temperature that does not adversely affect the thermal budget of the fabrication process, to desorb water from the layer. The layer can be heated, for example, to a temperature equal to or greater than about 100° C. for a time as short as a few seconds.

If the optical properties of the insulator layer as measured on the optical gratings or grating-like structures before and after heating are different, that difference is an indication that water was first adsorbed and then desorbed from the insulator layer, which, in turn, is an indication that the insulator layer was damaged by the processing environment. If no difference in optical properties is observed after heating, that is an indication that no water was adsorbed as a result of the processing environment and that no damage was inflicted on the insulator layer by the processing environment.

In accordance with one embodiment the amount of change in the measured optical properties before and after heating are quantized and are used to judge the amount of water adsorbed and hence the amount of damage sustained by insulator layer 28 as a result of subjecting that layer to a processing environment such as a plasma environment. An in-line technique for determining and quantizing process-induced water adsorption and damage in insulator layers is constructed as follows. Insulator layers such as low-k insulator layers are processed, optical properties are measured on gratings or grating-like structures, the insulating layers are heated, the optical properties are remeasured, and the optical properties measured before and after the heating are compared. The results of the comparison are correlated with actual water adsorption and damage to the insulator layer to quantize the damage determined by the non-destructive in-line technique. The actual water adsorption and damage can be determined on test substrates, for example, by the destructive SEM or TEM techniques described above. Using such destructive techniques, a table of water adsorption and hence layer damage versus change in optical properties can be constructed. Subsequent in-line non-destructive measuring-heating-remeasuring comparisons can be quantized by comparison to such a table.

In practice, an insulator layer such as a low-k insulator layer that may have been damaged by exposure to a processing environment can be inspected by the above-described in-line measurement comparison. A knowledge of the correlation between the in-line, non-destructive measurement comparison and actual water adsorption and damage (for example by consulting a table as constructed above) allows a determination to be made as to the extent to which the insulator layer may have adsorbed water and been damaged. In response to this determination a decision can be made as to whether the IC fabrication can continue, whether the IC fabrication can continue after repair of the damaged insulator layer, or whether fabrication of the IC should be terminated because of extensive damage to the insulator layer. For example, if the water adsorption and damage to the insulator layer is less than some threshold amount, fabrication of the IC continues without interruption. But if the amount of water adsorption and damage is greater than a first predetermined level but less than a second predetermined level, the fabrication can continue only after repair of the damaged insulator layer. If, instead, the damage to the insulator layer is greater than the second predetermined level, the fabrication should be terminated.

While at least one exemplary embodiment has been presented in the foregoing detailed description, it should be appreciated that a vast number of variations exist. It should also be appreciated that the exemplary embodiments are only examples, and are not intended to limit the scope, applicability, or configuration of the invention in any way. Rather, the foregoing detailed description will provide those skilled in the art with a convenient road map for implementing the exemplary embodiments. It should be understood that various changes can be made in the function and arrangement of elements without departing from the scope of the invention as set forth in the appended claims and the legal equivalents thereof.

1. A method for fabricating an integrated circuit comprising:
forming an integrated circuit feature overlying a semiconductor substrate;
depositing a layer of low dielectric constant insulator overlying the circuit feature;
subjecting the layer of low dielectric constant insulator to a processing environment;
measuring properties of the low dielectric constant insulator overlying the circuit feature by scatterometry;
heating the low dielectric constant insulator to drive off adsorbed water;
remeasuring properties of the low dielectric constant insulator overlying the circuit feature by scatterometry following such heating;
comparing results of the measuring and the remeasuring and on the basis of the comparing, determining if the low dielectric constant insulator was damaged by the processing environment.

2. The method of claim 1 wherein subjecting the layer of low dielectric constant insulator to a processing environment comprises plasma etching the layer.

3. The method of claim 1 wherein subjecting the layer of low dielectric constant insulator to a processing environment comprises:
applying and patterning a layer of photoresist overlying the layer of low dielectric constant insulator;
performing a processing step using the patterned photoresist as a process mask; and
removing the patterned photoresist in a plasma reaction.

4. The method of claim 1 wherein measuring and remeasuring by scatterometry comprises:
identifying a periodic, grating-like pattern in the layer of low dielectric constant insulator; and
directing scatterometry radiation on the periodic, grating-like pattern.

5. The method of claim 1 wherein measuring and remeasuring by scatterometry comprises:
forming a grating structure in a portion of the low dielectric constant insulator overlying a scribe grid area of the semiconductor substrate; and
directing scatterometry radiation on the grating structure.

6. The method of claim 1 further comprising quantizing any damage that may have occurred to the low dielectric constant material by the plasma environment in response to comparing results.

7. The method of claim 6 further comprising determining, in response to the quantizing, if processing of the integrated circuit should: continue, continue after repair of the layer of low dielectric constant insulator, or terminate.

8. The method of claim 1 wherein heating comprises heating to a temperature greater than or equal to 100° C.

9. The method of claim 1 wherein measuring properties and remeasuring properties each comprises measuring optical properties of the low dielectric constant insulator and wherein comparing comprises comparing optical properties determined by the measuring and the remeasuring, the method further comprising determining an amount of water adsorbed as a result of subjecting the layer of low dielectric constant insulator to the processing environment.

10. A method for fabricating an integrated circuit comprising:
depositing a layer of dielectric material overlying a semiconductor substrate;
plasma etching the layer of dielectric material to form a pattern in the dielectric material;
measuring the optical properties of the layer of pattered dielectric material by scatterometry;
heating the layer of patterned dielectric material;
remeasuring the optical properties of the layer of patterned dielectric material by scatterometry after heating;
comparing the measured and remeasured optical properties; and
in response to the comparing, determining extent of change in the layer of dielectric material caused by the plasma etching.

11. The method of claim 10 further comprising determining, in response to the comparing, an amount of water adsorbed by the layer of dielectric material as a result of the plasma etching.

12. The method of claim 10 wherein a plurality of integrated circuits is formed in and on the semiconductor substrate, the method further comprising:
identifying a periodic, grating-like pattern in a portion of the dielectric material associated with each of the plurality of integrated circuits;
during measuring and remeasuring, directing scatterometry radiation on the periodic, grating-like pattern on selected ones of the plurality of integrated circuits.

13. The method of claim 10 further comprising continuing processing of the integrated circuit in response to determining that the extent of change in the layer of dielectric material is less than a threshold amount.

14. A method of fabricating an integrated circuit comprising:
partially fabricating an integrated circuit structure including subjecting a layer of low dielectric constant dielectric material to a processing environment;
performing an in-line diagnostic technique to determine whether the layer of low dielectric constant dielectric material was damaged by the processing environment, the in-line diagnostic technique comprising:
measuring the optical properties of the layer of low dielectric constant dielectric material;
heating the layer of low dielectric constant dielectric material;
remeasuring the optical properties of the layer of low dielectric constant dielectric material after heating; and
comparing the measured and remeasured optical properties; and
determining, in response to the comparing, whether to continue to process the partially fabricated integrated circuit structure.

15. The method of claim 14 wherein measuring the optical properties and remeasuring the optical properties comprises measuring and remeasuring the optical properties by scatterometry.

16. The method of claim 14 further comprising determining the amount of water adsorbed by the low dielectric constant dielectric material as a result of subjecting the layer to a processing environment by comparing the measured and remeasured optical properties.

17. The method of claim 16 wherein determining whether to continue comprises comparing the determined amount of water adsorbed to a threshold value.

18. The method of claim 14 wherein subjecting the layer to a processing environment comprises an action selected from the group consisting of plasma etching the layer, removing photoresist from the layer by a plasma resist removal process, and cleaning the surface of the layer with a plasma cleaning process.
